(19) United States
(12) Patent Application Publication
(10) Pub. No.: US 2009/0017597 A1
(43) Pub. Date: Jan. 15, 2009

(54) METHOD FOR MANUFACTURING SHALLOW TRENCH ISOLATION

(75) Inventors: PETER HAI JUN ZHAO, HSINCHU CITY (TW); YU CHI CHEN, HSINCHU CITY (TW); YU SHENG LIU, TAICHUNG COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: PROMOS TECHNOLOGIES INC., Hsinchu (TW)

(21) Appl. No.: 11/969,726

(22) Filed: Jan. 4, 2008

(30) Foreign Application Priority Data
Jul. 11, 2007 (TW) 096125160

(51) Int. Cl. H01L 21/762

(52) U.S. Cl. 438/432; 257/E21.547

(57) ABSTRACT

A method for manufacturing semiconductor shallow trench isolation is performed as follows. First, a semiconductor substrate including at least one shallow trench is provided, and the shallow trench is filled with Spin-On-Dielectric (SOD) material, e.g., polysilazane, to form a SOD material layer. Then, the SOD material layer is subjected to a planarization process. Oxygen ions are implanted into the SOD material layer to a predetermined depth, and a high temperature process is performed afterwards to transform the portion of the SOD material layer having oxygen ions into a silicon oxide layer. The oxygen ions can be implanted by plasma doping, immersion doping or ion implantation.

### BACKGROUND OF THE INVENTION

(A) Field of the Invention

The present invention relates to a semiconductor manufacturing process, and more particularly, to a method for manufacturing semiconductor shallow trench isolation (STI).

(B) Description of the Related Art

In making semiconductor shallow trench isolation, the shallow trenches are filled with an isolation layer for insulation between neighboring active areas. With the downsizing of the semiconductor devices, high density plasma chemical vapor deposition (HDP CVD) is mainly used to deposit an isolation layer such as silicon oxide in the shallow trenches.

However, as semiconductor devices enter nano-meter (nm) generation, the aspect ratio of the shallow trench is increased. For instance, the aspect ratio of a shallow trench of 70 nm will significantly increase to 7:1, and consequently even silicon oxide is filled by HDP CVD, and voids may occur in the shallow trench due to worse step coverage.

Therefore, a spin-on-dielectric (SOD) technology is used. After the shallow trench is filled with the SOD material, a thermal process is conducted to remove the solvent. Then, the wafer is placed in a furnace with steam at a high temperature of approximately 800˜1000° C. to undergo a high temperature oxidation process for around 30 minutes, so as to transform the SOD material into silicon oxide.

Generally, silicon oxide made from SOD material is less dense, so the etch rate is higher, regardless of whether wet etching or dry etching is performed afterwards. Moreover, because the transformation of SOD material uses steam diffusion in the SOD material, poor diffusion is one of the reasons for the lesser density. As a result, erosion would be generated in the SOD material during cleaning by hydrofluoric acid (HF), and it is harmful to the sequential process and reduces production yield.

FIG. 1 shows a traditional isolation structure 10 comprising a silicon substrate 16, and shallow trenches 11 are filled with SOD material 14. An oxide layer 12 and a nitride liner 13 are formed between the SOD material 14 and the shallow trench 11. The nitride liner 13 can prevent the shoulder and sidewall of the shallow trench 11 from being oxidized when the SOD material 14 undergoes a high temperature oxidation process and is transformed into an oxide layer of higher quality. The oxide layer 12 is used to decrease the stress between the nitride liner 13 and the silicon substrate 16. In the following HF cleaning, erosion may be generated in the less dense SOD material. Therefore, the deposited polysilicon layer 15 in the erosion is not easily removed and will remain sometimes, resulting in decreasing production yield.

### SUMMARY OF THE INVENTION

The present invention provides a semiconductor manufacturing process, and more particularly, a method for manufacturing semiconductor shallow trench isolation, by which there is no need to use the high temperature oxidation process which uses steam to transform the SOD material in the shallow trench to silicon oxide, and the quality of silicon oxide is improved to reduce the likelihood of erosion generated by the traditional SOD process, thereby increasing the manufacturing yield.

In accordance with an embodiment of the present invention, a method for manufacturing semiconductor shallow trench isolation is performed as follows. First, a semiconductor substrate including one or more shallow trenches is provided, and the shallow trench is filled with SOD material that forms a SOD material layer. Then, the SOD material layer is subjected to a planarization process such as chemical mechanical polishing (CMP). Oxygen ions are implanted into the SOD material layer to a predetermined depth, and a high temperature process is performed afterwards to transform the portion of the SOD material layer having oxygen ions into a silicon oxide layer.

The SOD material is preferably polysilazane. The oxygen ions can be implanted by plasma doping, immersion doping or ion implantation.

There is no need to introduce steam in the high temperature process; therefore, the oxidation of the shoulder or sidewall of the shallow trench would not become an issue. In turn, the nitride liner for protection is not needed, and the process can be simplified.

### BRIEF DESCRIPTION OF THE DRAWINGS

FIG. 1 shows a known shallow trench isolation structure; and

FIGS. 2 through 9 show a process for making shallow trench isolation in accordance with an embodiment of the present invention.

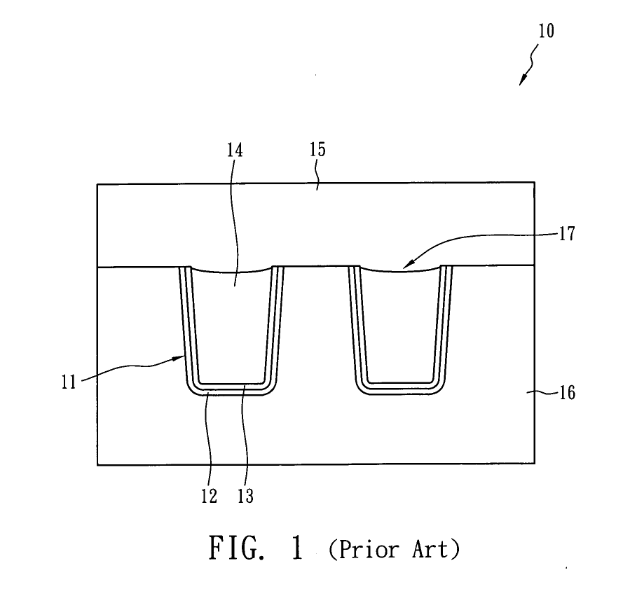

### DETAILED DESCRIPTION OF THE INVENTION

The method for manufacturing shallow trench isolation is explained with reference to the appended drawings.

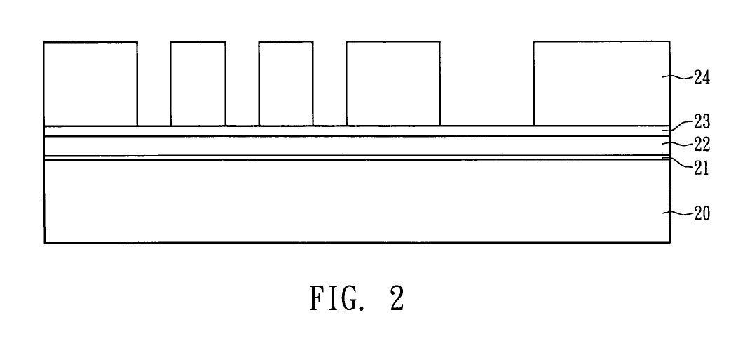

FIGS. 2 through 9 show a method for manufacturing shallow trench isolation in accordance with an embodiment of the present invention, in which an oxygen ion doping or implanting step followed by a high temperature process is performed to intensify the surface of the SOD material, so as to avoid erosion in the SOD material from an HF process performed afterwards.

In FIG. 2, a pad oxide layer 21 and a pad nitride layer 22 are formed on a semiconductor substrate 20. In order to prevent the reflection of the pad nitride layer 22 during lithography, a bottom anti-reflection (BARC) layer 23 and a photoresist layer 24 with a figure are formed. The left portion of FIG. 2 shows an array area, and the right portion of FIG. 2 shows a peripheral area.

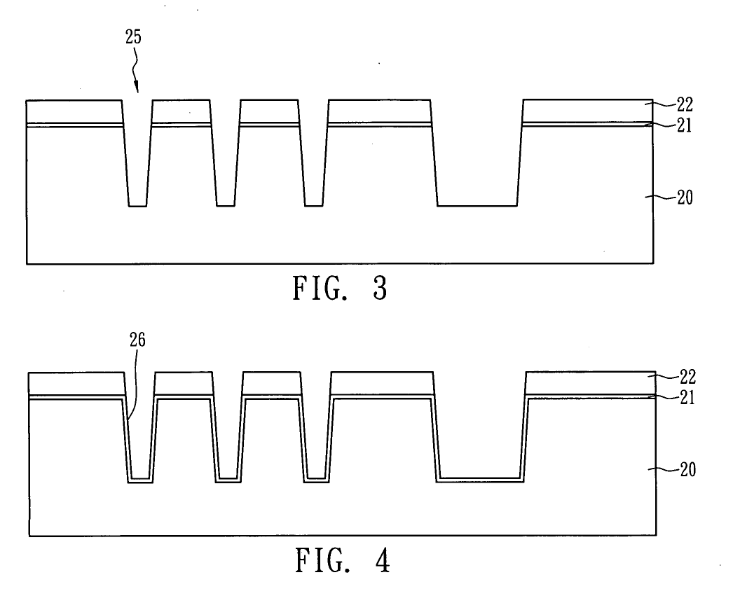

In FIGS. 3 and 4, shallow trenches 25 are formed in the semiconductor substrate 20 by etching, and the BARC layer 23 and the photoresist layer 24 are removed. Then, an oxide layer 26 (wall oxide layer) is formed on the shallow trenches 25.

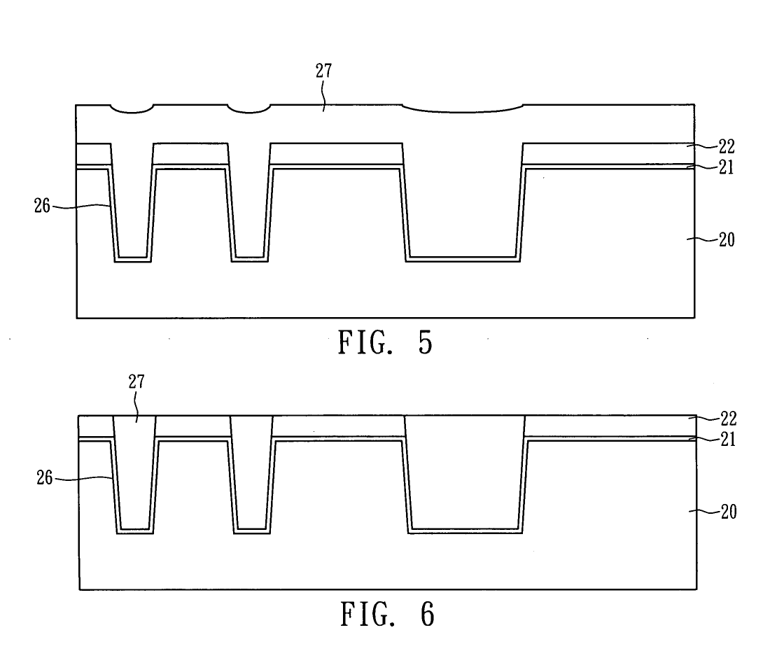

In FIGS. 5 and 6, a SOD material layer 27 is deposited, and as a consequence the shallow trenches 25 are filled with the SOD material layer 27. The solvent in the SOD material layer 27 is removed in a high temperature furnace and the surface of the SOD material layer 27 is hardened in a nitrogen atmosphere. Sequentially, the SOD material layer 27 is planarized by CMP. In an embodiment, the SOD material layer 27 comprises polysilazane or perhydro-polysilazane.

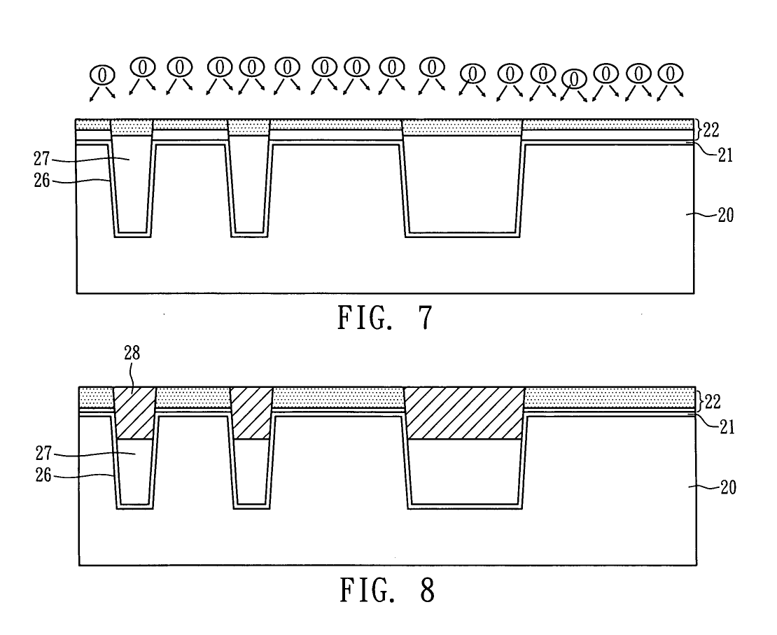

In FIG. 7, oxygen ions are implanted into a depth between 100 and 1000 angstroms from the surface of the SOD material layer 27 by plasma doping (PLAD), immersion doping, ion implantation or the like, and the depth is preferably between 100 and 200 angstroms. Implantation dosage is greater than 1E 17 atoms/cm², and the energy is between 0.5 and 10 KeV In this embodiment, the energy is 3 KeV Sequentially, a high temperature process is performed, for example, a rapid temperature processing (RTP) in a nitrogen environment with a temperature higher than 950° C., or a decoupled plasma nitrification (DPN), and thereby, the oxygen ions are further diffused to a predetermined depth as shown in FIG. 8.

In the high temperature process, the nitride atoms of polysilazane are replaced with oxygen atoms as below, and thereby, the portion of the SOD material layer 27 is transformed into a silicon oxide layer 28.

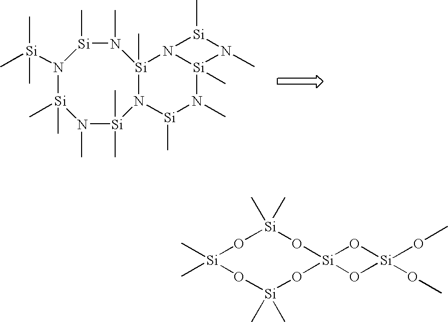

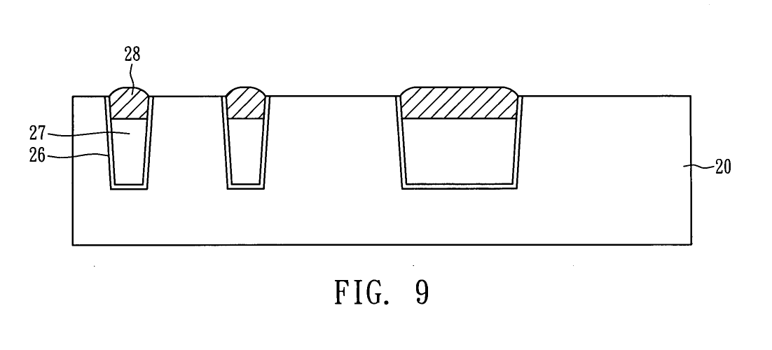

In FIG. 9, the pad nitride layer 22 and the pad oxide layer 21 are removed, and then the wafer is subjected to the sequential processes.

In comparison with the diffusion limitation in the traditional high temperature oxidation using steam, the oxygen ion implantation or doping can effectively control the implanting depth, and therefore, the density or hardness of the surface of the silicon oxide transformed from the SOD material can be increased. By intensifying the surface of the SOD material layer 27, the erosion in the SOD material layer 27 generated in the process removing the pad nitride layer or the use of hydrofluoric acid before the formation of the sacrificial oxide layer or gate oxide layer can be avoided, so that the polysilicon remaining is decreased, thereby increasing the production yield.

The method for manufacturing shallow trench isolation of the present invention does not need the high temperature oxidation process using steam, so SOD is compatible with dynamic random access memory (DRAM), flash memory and logic circuit processes. Moreover, the nitride liner is not needed according to the present invention, thereby providing a larger process window for shallow trench filling process and simplifying the manufacturing process.

The above-described embodiments of the present invention are intended to be illustrative only. Numerous alternative embodiments may be devised by those skilled in the art without departing from the scope of the following claims.

What is claimed is:

1. A method for manufacturing shallow trench isolation, comprising:
providing a semiconductor substrate including at least one shallow trench;
depositing spin-on-dielectric (SOD) material in the shallow trench to form a SOD material layer;
planarizing the SOD material layer;
implanting oxygen ions into the SOD material layer to a first predetermined depth; and
performing a high temperature process to transform the portion of the SOD material layer having oxygen ions into a silicon oxide layer.

2. The method of claim 1, wherein the SOD material comprises polysilazane or perhydro-polysilazane.

3. The method of claim 1, wherein the oxygen ions are implanted by plasma doping, immersion doping or ion implantation.

4. The method of claim 1, wherein the first predetermined depth is between 100 and 1000 angstroms.

5. The method of claim 1, wherein the first predetermined depth is between 100 and 200 angstroms.

6. The method of claim 1, wherein the dosage of implanting oxygen ions is greater than 1E17 atoms/cm².

7. The method of claim 1, wherein the energy of implanting oxygen ions is between 0.5 KeV and 10 KeV.

8. The method of claim 1, further comprising a step of forming an oxide layer on the shallow trench before depositing SOD material.

9. The method of claim 1, wherein the oxygen ions are diffused to a second predetermined depth in the high temperature process, and the second predetermined depth is larger than the first predetermined depth.

10. The method of claim 1, wherein the high temperature process is performed in a nitrogen environment.

11. The method of claim 1, wherein the high temperature process is performed at a temperature higher than 950° C.

12. The method of claim 1, wherein the high temperature process is a rapid temperature processing or a decoupled plasma nitrification.

13. The method of claim 1, wherein the high temperature process is performed without steam.
